(19) United States
(12) Patent Application Publication
(10) Pub. No.: US 2025/0275332 A1
(43) Pub. Date: Aug. 28, 2025

(54) STRETCHABLE DISPLAY DEVICE

(71) Applicant: UIF (University Industry Foundation), Yonsei University, Seoul (KR)

(72) Inventors: Hyun Jae Kim, Seoul (KR); Hye Jin Son, Seoul (KR); Won Kyung Min, Seoul (KR); Ji Yeong Park, Seoul (KR); Sun Min Song, Goyang-si (KR)

(21) Appl. No.: 19/062,102

(22) Filed: Feb. 25, 2025

(30) Foreign Application Priority Data
Feb. 27, 2024 (KR) 10-2024-0028137

(51) Int. Cl. H10H 29/34; G09G 3/00; G09G 3/32; H10H 29/49

(52) U.S. Cl. CPC H10H 29/34; G09G 3/035; G09G 3/32; H10H 29/49; G09G 2300/0439; G09G 2300/0819; G09G 2300/0842; G09G 2300/0861; G09G 2320/0233

(57) ABSTRACT

Proposed is a stretchable display device. The stretchable display device includes a plurality of main pixels, a plurality of hidden pixels, a first main pixel, and a first hidden pixel corresponding to the first main pixel. A first hidden pixel value is determined on the basis of a first main pixel value.

### CROSS REFERENCE TO RELATED APPLICATION

The present application claims priority to Korean Patent Application No. 10-2024-0028137, filed Feb. 27, 2024, the entire contents of which are incorporated herein for all purposes by this reference.

### BACKGROUND

### Technical Field

The present disclosure relates to a stretchable display device capable of resolution correction even though a stretchable display is stretched.

### Description of the Related Art

The present disclosure is derived from research conducted as part of Technology Development for Nano and Materials (R&D) by Ministry of Science and ICT (Project Unique Number: 1711181611, Project Number: 2020M3H4A1A02084896, Project Management Agency: Research Foundation of Korea, Research Project Name: Biaxial stretch-sensitive AMLED display backplane material/element technology, Project Performing Institution: Yonsei University, Research Period: Jan. 1, 2024 to Dec. 31, 2024). Meanwhile, there is no property interest of the Korean government in any aspect of the present disclosure.

A stretchable display device is a next-generation display in which a display screen is elastically stretched, but the stretchable display device field still requires extensive research. Depending on future research outcomes, stretchable display devices are expected to be applied to various products, such as wearable devices attached to the body or clothing, head-up displays embedded in vehicle windshields that expand or contract minutely according to external temperature, and other display devices requiring display screen adjustment capabilities.

One of the technical difficulties of the stretchable display device is that the resolution of the pixel is changed before and after the stretchable display device is stretched. When the stretchable display device is stretched, the number of pixels per unit area is reduced, thereby resulting in a change in resolution. As such, when the resolution is changed due to the stretching of the display, the image displayed on the display may be distorted.

Therefore, in order to prevent an image displayed on the display device from being distorted, a technology capable of maintaining a constant resolution of the stretchable display device even though the display device is stretched is required.

### SUMMARY

According to an aspect of the disclosure, since a value of a hidden pixel that is activated when a display is stretched is determined on the basis of values of adjacent main pixels, a hidden pixel area is simplified, so that a display having a higher resolution is capable of being designed.

In addition, according to an aspect of the disclosure, since the main pixel and the hidden pixel are alternately disposed within the stretchable display, the number of main pixels within the unit area is increased, so that the resolution of the display is capable of being increased.

Furthermore, according to an aspect of the disclosure, the number of wiring for controlling the stretchable display device is reduced, so that the production cost of the stretchable display device may be reduced.

According to an aspect of the present disclosure, there is provided a stretchable display device provided with a plurality of main pixels and a plurality of hidden pixels, the stretchable display device including: a first main pixel; and a first hidden pixel corresponding to the first main pixel, wherein a first hidden pixel value is determined on the basis of a first main pixel value.

In addition, the first hidden pixel may be positioned adjacent to the first main pixel.

In addition, the first hidden pixel value may be determined by replicating the first main pixel value.

In addition, the replicating of the first main pixel value may be performed such that a luminance of the first hidden pixel is equal to a luminance of the first main pixel.

In addition, in the performing that the luminance of the first hidden pixel is equal to the luminance of the first main pixel, when a control signal for the first hidden pixel is generated, the control signal may be applied from an anode of the first main pixel to an anode of the first hidden pixel.

In addition, in the stretchable display device, the main pixels and the hidden pixels may be alternately disposed.

In addition, the stretchable display device may further include: at least one hidden pixel control line; and at least one data line, wherein the hidden pixel control line and the data line may be alternately disposed.

In addition, in the stretchable display device, the hidden pixel control line and the data line may be disposed parallel to each other.

According to an aspect of the present disclosure, there is provided a stretchable display device provided with a plurality of main pixels and a plurality of hidden pixels, the stretchable display device including: a second hidden pixel; and a plurality of second main pixels corresponding to the second hidden pixel, wherein a second hidden pixel value may be determined on the basis of a plurality of second main pixel values.

In addition, the second hidden pixel may be positioned adjacent to the plurality of second main pixels.

In addition, the second hidden pixel value may be determined by using an average value or a weighted average value of the plurality of second main pixel values.

In addition, the determining of the second hidden pixel value by using the average value or the weighted average value of the plurality of second main pixel values may be performed such that a luminance of the second hidden pixel is equal to an average value or a weighted average value of a luminance of the plurality of second main pixels.

In addition, in the performing that the luminance of the second hidden pixel is equal to the average value or the weighted average value of the luminance of the plurality of second main pixels, a voltage may be distributed by using a capacitor.

In addition, in the stretchable display device, the main pixels and the hidden pixels may be alternately disposed.

In addition, the stretchable display device may further include: at least one hidden pixel control line; and at least one data line, wherein the hidden pixel control line and the data line may be alternately disposed.

In addition, in the stretchable display device, the hidden pixel control line and the data line may be disposed parallel to each other.

In the stretchable display device according to an aspect of the disclosure, the pixel values of the adjacent main pixels are used when the hidden pixel is activated, so that the hidden pixel and the related configuration are simplified, thereby being capable of designing the stretchable display device having a high-resolution and being also capable of reducing the production cost of the stretchable display device.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a conceptual view illustrating a stretchable display according to an embodiment of the present disclosure;

FIG. 2 is a circuit diagram illustrating a main pixel and a hidden pixel according to an embodiment of the present disclosure;

FIG. 3 is a conceptual view illustrating a pixel arrangement and a wiring of the stretchable display according to an embodiment of the present disclosure;

FIG. 4 is a conceptual view illustrating the stretchable display according to an embodiment of the present disclosure;

FIG. 5 is a circuit diagram illustrating the main pixel and the hidden pixel according to an embodiment of the present disclosure; and

FIG. 6 is a conceptual view illustrating the pixel arrangement and the wiring of the stretchable display according to an embodiment of the present disclosure.

### DETAILED DESCRIPTION

Like reference numerals refer to like elements throughout the specification. The present specification does not describe all elements of embodiments, and the general content in the technical field to which the disclosed present disclosure pertains or duplicated content between the embodiments is omitted. The term “˜ part” used in the specification may be implemented by software or with hardware, and according to embodiments, a plurality of “˜ parts” may be implemented with one element, or one “part” may include a plurality of elements.

Throughout the specification, when it is mentioned that a first part is “connected” with a second part, this includes the case where they are electrically connected.

In addition, when it is mentioned that a first part is “connected” with a second part, this includes not only the case where they are directly connected but also the case where they are indirectly connected, and the indirect connection means the case where any other component(s) is connected between the first and second parts.

In addition, when it is mentioned that a part “includes” a certain component, this means that any other component(s) may be further included, rather than excluding any other component(s), unless otherwise stated.

The term “˜part” used herein is a unit for processing at least one function or operation, and may mean, for example, a software, FPGA, or hardware component. A function provided by “˜part” may be performed separately by a plurality of components, or may be integrated with any other additional component(s). In the specification, the term “˜part” is not necessarily limited to software or hardware, and may be configured to reside in an addressable storage medium or to reproduce one or more processors.

The terms such as first, second, and so on are used to distinguish one component from another component, and the components are not limited by the above terms.

A singular expression includes a plural expression, unless there are obvious exceptions in the context.

In each step, a reference sign is used for convenience of description, and the reference sign does not describe the order of respective steps. Each step can be carried out to be different from the specified order unless the specific order is clearly stated in the context.

Hereinafter, the operation principle and embodiments of the disclosed present disclosure will be described with reference to the accompanying drawings.

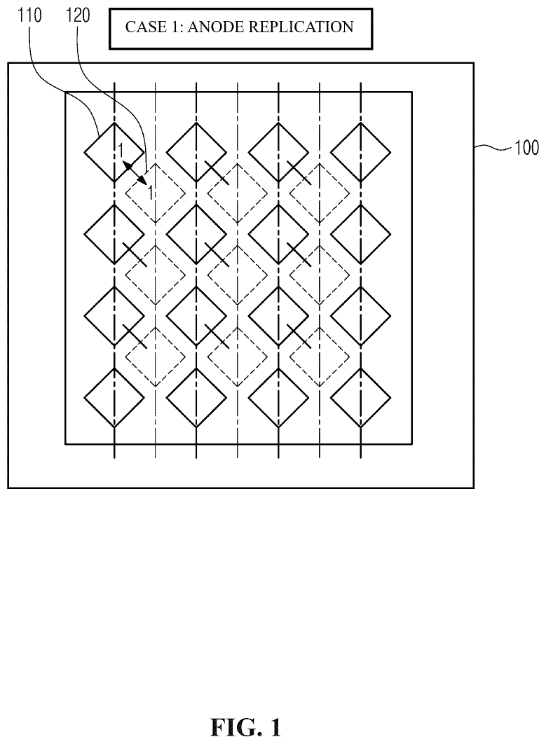

FIG. 1 is a conceptual view illustrating a stretchable display according to an embodiment of the present disclosure.

The stretchable display device may be a display device capable of displaying an image even though the display device is warped or stretched. The stretchable display device may have a high flexibility compared to that of a conventional display device. That is, the shape of the stretchable display device may be freely changed according to an operation of a user, such as when the user warps or stretches the stretchable display device.

For example, when the user grasps and pulls an end of the stretchable display device, the stretchable display device may be stretched by the user's force. Alternatively, when the user arranges the stretchable display device on a non-flat wall surface, the stretchable display device may be arranged such that the stretchable display device is bent along the shape of the wall surface. In addition, when the force applied by the user is removed, the stretchable display device may revert back to the original shape thereof.

A main pixel 110 and a hidden pixel 120 may emit light of any one of red, green, and blue colors according to a light color of a light-emitting element contained in each pixel.

In some embodiments, each of the main pixel 110 and the hidden pixel 120 may be a light-emitting element such as an Organic Light-Emitting Diode (OLED), a Polymer Light-Emitting Diode (PLED), a Quantum Dot (QD), a Light-Emitting Diode (LED), and so on, but is not limited thereto.

In some embodiments, a stretchable display device 100 may include a plurality of main pixels 110 and a plurality of hidden pixels 120. In some embodiments, the main pixel 110 may be a pixel that is configured to be activated regardless of whether the stretchable display device 100 is stretched. That is, a driving state of the main pixel 110 may remain the same before and after the stretchable display device 100 is stretched.

In some embodiments, the hidden pixel 120 included in the stretchable display device 100 may be a pixel configured such that whether the pixel is activated or not is determined according to whether the stretchable display device 100 is stretched or not. In some embodiments, the hidden pixel 120 may be activated when the stretchable display device 100 is stretched to a level equal to or more than a predetermined level. In other embodiments, the activation status of each of the plurality of hidden pixels included in the stretchable display device 100 may be different from each other. In an example, when only a portion of the stretchable display device 100 is stretched, only the hidden pixels 120 included in the stretched portion may be activated and other hidden pixels may not be activated.

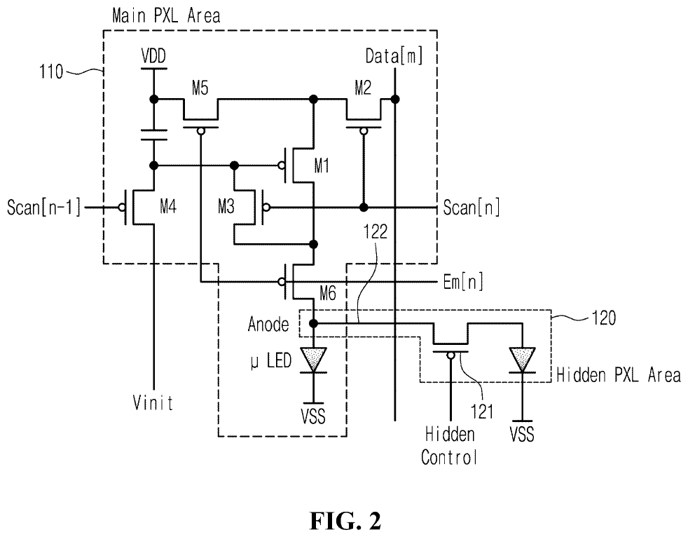

In some embodiments of the present disclosure, the main pixel 110 and the hidden pixel 120 may have a corresponding relationship. Preferably, a specific hidden pixel 120 may have a corresponding specific main pixel 110. In an example, the corresponding main pixel 110 and the corresponding hidden pixel 120 may be positioned adjacent to each other. In an embodiment, a pixel value of the hidden pixel 120 may be determined on the basis of a pixel value of the corresponding main pixel 110. For example, the pixel value of the hidden pixel 120 may be interlocked to the pixel value of the main pixel 110. Preferably, the pixel value of the hidden pixel 120 may be the same as the pixel value of the main pixel 110. In this situation, the pixel value of the hidden pixel 120 may be determined by replicating the pixel value of the main pixel 110. This will be described later in detail with reference to FIG. 2.

FIG. 2 is a circuit diagram illustrating a main pixel and a hidden pixel according to an embodiment of the present disclosure.

Referring to FIG. 2, the main pixel 110 and the hidden pixel 120 according to some embodiments of the present disclosure may be connected to each other through an anode 122 of each of the main pixel and the hidden pixel. In some embodiments, whether the hidden pixel 120 is activated may be determined according to whether a control signal applied from a hidden pixel control line 121 of the hidden pixel 120 is activated. In an embodiment, when the control signal is activated from the hidden pixel control line 121 of the hidden pixel 120, the hidden pixel 120 may be activated. In some embodiments, when the hidden pixel 120 is activated, a main pixel value may be applied from the anode of the main pixel to the anode of the hidden pixel. In an embodiment, the pixel value of the main pixel may be directly applied to the hidden pixel 120. Through this, the hidden pixel 120 may have the luminance the same as the luminance of the main pixel 110.

The main pixel 110 may receive a power supply voltage VDD and a data signal Data[m], and may be driven by being selected through scan signals Scan[n] and Scan[n−1]. For this purpose, as illustrated in FIG. 2, the main pixel 110 may include a first PMOS transistor M1, a second PMOS transistor M2, a third PMOS transistor M3, a fourth PMOS transistor M4, a fifth PMOS transistor M5, a sixth PMOS transistor M6, and a micro LED μLED.

The sixth PMOS transistor M6 may be referred to as a micro LED driving transistor driving a micro LED in the present disclosure, and may be electrically connected to the anode 122 of the hidden pixel 120. The sixth PMOS transistor M6 may be in a conducting state (ON) or in a blocking state (OFF) according to a driving signal Em[n] input to a gate terminal.

Meanwhile, the hidden pixel 120 may be controlled according to a hidden pixel control signal (hidden control). Furthermore, when the hidden pixel 120 is activated, a pixel value may be provided from an anode 122 that is electrically connected to the sixth PMOS transistor M6 of the main pixel 110. For example, when the hidden pixel 120 is activated, the hidden pixel 120 may receive a pixel value on the basis of a voltage or a current of the anode 122 electrically connected to the sixth PMOS transistor M6 of the main pixel 110.

In addition, on the basis of a pixel value provided through the anode 122, the hidden pixel 120 may duplicate the pixel value of the main pixel 110, or may set a final luminance by calculating the weighted average of a plurality of adjacent main pixel values.

In a conventional stretchable display device, it is common that a hidden pixel is operated independently of a main pixel. Therefore, although a hidden pixel area of the stretchable display device is activated only when the stretchable display device is stretched, a hidden pixel area has the same complexity as a main pixel area that is always activated. In addition, in the entire of the stretchable display device, a wiring such as a data line and so on is required to be realized on the hidden pixel area. Therefore, not only did the number of pixels per unit area of the stretchable display decrease, but there was also a problem of excessive production cost due to additional wiring and other factors. In the stretchable display device according to the present disclosure, since the hidden pixel is configured such that the hidden pixel replicates the pixel value of the main pixel adjacent to the hidden pixel, the configuration of the hidden pixel may be simplified. Therefore, the complexity of the hidden pixel area may be reduced. In addition, the stretchable display device according to the present disclosure requires only the hidden pixel control line for controlling the hidden pixel in the hidden pixel, and does not require an additional data line. Therefore, not only may more pixels be disposed in the display device, but also the cost for producing the stretchable display device may be reduced.

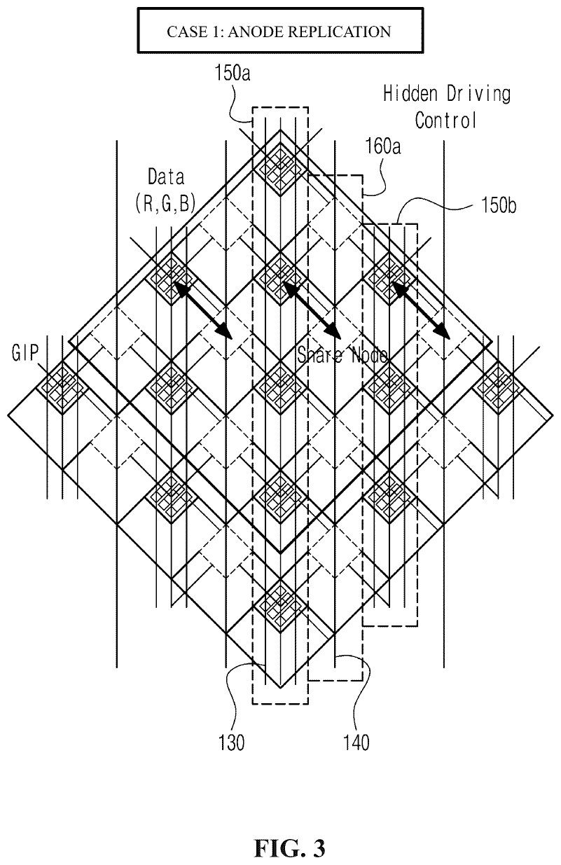

FIG. 3 is a conceptual view illustrating a pixel arrangement and a wiring of the stretchable display according to an embodiment of the present disclosure.

Referring to FIG. 3, in the stretchable display device according to some embodiments of the present disclosure, main pixel columns 150a and 150b and a hidden pixel column 160a may be alternately arranged so that the main pixel columns 150a and 150b and the hidden pixel column 160a are positioned parallel to a diagonal direction of the stretchable display device. Referring to FIG. 3, the stretchable display device may include a plurality of main pixel columns and a plurality of hidden pixel columns. In some embodiments, the main pixel column of the stretchable display device may be a pixel column formed of at least one main pixel (i.e., including only the main pixel). At this time, the main pixel column does not necessarily have to be physically partitioned within the stretchable display device. That is, it should be interpreted that the main pixel column according to some embodiments of the present disclosure refers to a pixel arrangement form on the stretchable display. In some embodiments, the hidden pixel column of the stretchable display device may be a pixel column formed of at least one hidden pixel (i.e., including only the hidden pixel). As with the main pixel column, the hidden pixel column according to the present disclosure is not necessarily physically partitioned within the stretchable display device, and should be interpreted as a pixel arrangement form recognized according to the pixel arrangement.

Preferably, the main pixel column and the hidden pixel column according to the present disclosure may be disposed parallel to the diagonal direction of the stretchable display device. Referring to FIG. 3, both the main pixel columns 150a and 150b and the hidden pixel column 160a may be disposed parallel to the diagonal direction of the stretchable display device. In addition, in some embodiments of the present disclosure, the main pixel column and the hidden pixel column may not intersect each other. Preferably, the main pixel column and the hidden pixel column may be disposed alternately and/or parallel on the stretchable display. Referring to FIG. 3 again, after the main pixel column 150a and the hidden pixel column 160a are disposed parallel to each other, the main pixel column 150b may be disposed parallel to the hidden pixel column 160a on the stretchable display device.

The stretchable display device according to some embodiments of the present disclosure may include a data line 130 and a hidden pixel control line 140. In some embodiments, the data line 130 may be a path through which color, brightness, and/or contrast data from a display controller of the stretchable display is transmitted to each pixel. In an embodiment, the data line 130 may be a path for transmitting an RGB color value to the pixel.

In addition, as described above in FIG. 1 and FIG. 2, the hidden pixel control line 140 according to some embodiments of the present disclosure may be a wiring or a path for transmitting a signal related to whether each of the hidden pixels contained in the hidden pixel column 160a disposed on the stretchable display is activated.

Referring to FIG. 3 again, in the stretchable display device according to some embodiments of the present disclosure, the data line 130 and the hidden pixel control line 140 may be arranged alternately and/or parallel on the stretchable display device. Preferably, in the stretchable display, the data line 130 may be connected only to the main pixel columns 150a and 150b, and the hidden pixel control line 140 may be connected only to the hidden pixel column 160a. More preferably, in part or all of a cross-sectional area of the stretchable display device, the data line 130 and the hidden pixel control line 140 may not intersect each other.

In a conventional stretchable display device, when a hidden pixel is used for correcting the image quality while the conventional stretchable display device is stretched, an arrangement in which a single main pixel is surrounded by a plurality of hidden pixels is common. Since this arrangement reduces the number of main pixels existing within the unit area of the stretchable display, there is a problem that the image quality of the stretchable display device is reduced. As described above, in the stretchable display device according to the present disclosure, the number of main pixels per unit area of the stretchable display may be increased by alternately arranging the main pixel column and the hidden pixel column on the stretchable display device. Through this, the problem of the reduction in the image quality of the stretchable display device may be significantly solved. In addition, due to the arrangement of the main pixel column and the hidden pixel column as described above, the number of data lines and the hidden pixel control lines may be significantly reduced. Specifically, according to the arrangement of the main pixel, the hidden pixel, the data line, and the hidden pixel control line of the stretchable display device disclosed in FIG. 3, the number of pixels per inch may be increased by 41% compared to that of the conventional technology, and the number of data channels used to produce the stretchable display device may be reduced by 33% compared to that of the conventional technology. Therefore, in the stretchable display device according to the present disclosure, the production cost may be significantly reduced while the reduction in the image quality according to the stretching is solved.

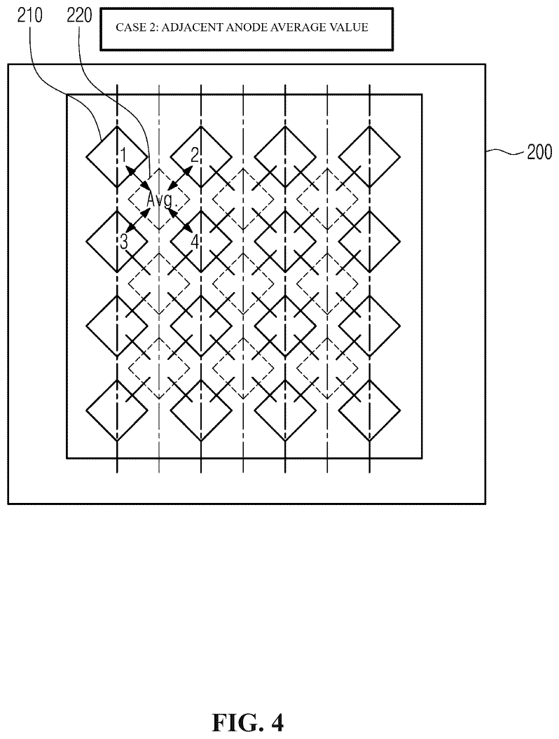

FIG. 4 is a conceptual view illustrating the stretchable display according to an embodiment of the present disclosure.

Referring to FIG. 4, a stretchable display device 200 according to an embodiment of the present disclosure may include a plurality of main pixels 210 and a plurality of hidden pixels 220. As described above in FIG. 1, the main pixel 210 may be a pixel that is configured to be activated regardless of whether the stretchable display device 200 is stretched. That is, a driving state of the main pixel 210 may remain the same before and after the stretchable display device 200 is stretched.

In some embodiments, the hidden pixel 220 included in the stretchable display device 200 may be a pixel configured such that whether the pixel is activated or not is determined according to whether the stretchable display device 200 is stretched or not. In some embodiments, the hidden pixel 220 may be activated when the stretchable display device 200 is stretched to a level equal to or more than a predetermined level. In other embodiments, the activation status of each of the plurality of hidden pixels included in the stretchable display device 200 may be different from each other. In an example, when only a portion of the stretchable display device 200 is stretched, only the hidden pixels 220 included in the stretched portion may be activated and other hidden pixels may not be activated.

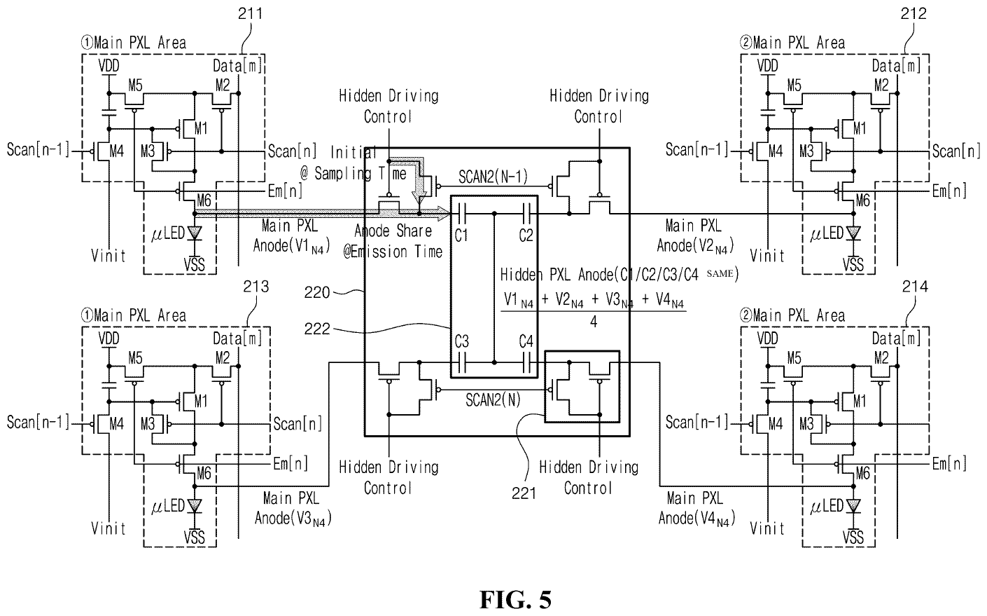

In some embodiments of the present disclosure, the main pixel 210 and the hidden pixel 220 may have a corresponding relationship. Preferably, a specific hidden pixel 220 may have a corresponding specific plurality of main pixels 210. In an example, the corresponding plurality of main pixels 210 and the hidden pixel 220 may be positioned adjacent to each other. In an embodiment, a pixel value of the hidden pixel 220 may be determined on the basis of a pixel value of each of the corresponding plurality of main pixels 210. For example, the pixel value of the hidden pixel 220 may be interlocked to the pixel values of the plurality of main pixels 210. Preferably, the pixel value of the hidden pixel 220 may be determined as an average value, a weighted average value, and/or a mode value of the pixel values of the corresponding plurality of main pixels 210. This will be described later in detail with reference to FIG. 5.

FIG. 5 is a circuit diagram illustrating the main pixel and the hidden pixel according to an embodiment of the present disclosure.

Referring to FIG. 5, the main pixels 211 to 214 and the hidden pixel 220 according to some embodiments of the present disclosure may be connected to each other through an anode of each of the main pixels and the hidden pixel. In some embodiments, whether the hidden pixel 220 is activated may be determined according to whether a control signal applied from a hidden pixel control line of the hidden pixel 220 is activated. In an embodiment, when the control signal is activated from the hidden pixel control line of the hidden pixel 220, the hidden pixel 220 may be activated. In some embodiments, when the hidden pixel 220 is activated, a main pixel value may be applied from the anode of the main pixels 211 to 214 to the anode of the hidden pixel. In an embodiment, the average value or the weighted average value of the pixel values of the main pixels 211 to 214 may be applied to the hidden pixel 220. Through this, the hidden pixel 220 may have the luminance value the same as an average value or a weighted average value of the luminance value of the main pixels 211 to 214. In some embodiments, specifically, determining the hidden pixel value of the hidden pixel 220 may be performed by distributing a voltage applied from the main pixels 211 to 214 by using a capacitor 222.

In a conventional stretchable display device, it is common that a hidden pixel is operated independently of a main pixel. Therefore, although a hidden pixel area of the stretchable display device is activated only when the stretchable display device is stretched, a hidden pixel area has the same complexity as a main pixel area that is always activated. In addition, in the entire of the stretchable display device, a wiring such as a data line and so on is required to be realized on the hidden pixel area. Therefore, not only did the number of pixels per unit area of the stretchable display decrease, but there was also a problem of excessive production cost due to additional wiring and other factors. In the stretchable display device according to the present disclosure, since the hidden pixel is configured such that the hidden pixel replicates the pixel value of the main pixel adjacent to the hidden pixel, the configuration of the hidden pixel may be simplified. Therefore, the complexity of the hidden pixel area may be reduced. In addition, the stretchable display device according to the present disclosure requires only the hidden pixel control line for controlling the hidden pixel in the hidden pixel, and does not require an additional data line. Therefore, not only may more pixels be disposed in the display device, but also the cost for producing the stretchable display device may be reduced.

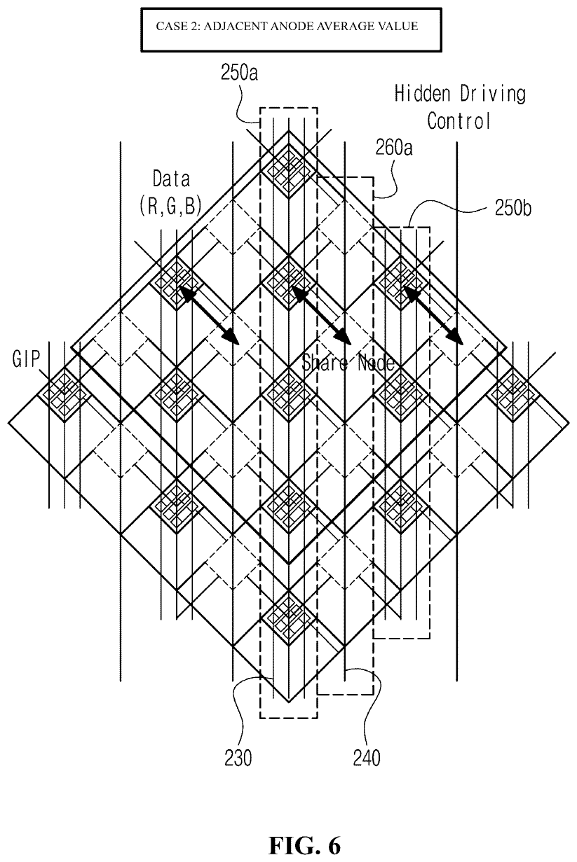

FIG. 6 is a conceptual view illustrating the pixel arrangement and the wiring of the stretchable display according to an embodiment of the present disclosure.

Referring to FIG. 6, in the stretchable display device according to some embodiments of the present disclosure, main pixel columns 250a and 250b and a hidden pixel column 260a may be alternately arranged so that the main pixel columns 250a and 250b and the hidden pixel column 260a are positioned parallel to a diagonal direction of the stretchable display device. Referring to FIG. 3, the stretchable display device may include a plurality of main pixel columns and a plurality of hidden pixel columns. In some embodiments, the main pixel column of the stretchable display device may be a pixel column formed of at least one main pixel (i.e., including only the main pixel). At this time, the main pixel column does not necessarily have to be physically partitioned within the stretchable display device. That is, it should be interpreted that the main pixel column according to some embodiments of the present disclosure refers to a pixel arrangement form on the stretchable display. In some embodiments, the hidden pixel column of the stretchable display device may be a pixel column formed of at least one hidden pixel (i.e., including only the hidden pixel). As with the main pixel column, the hidden pixel column according to the present disclosure is not necessarily physically partitioned within the stretchable display device, and should be interpreted as a pixel arrangement form recognized according to the pixel arrangement.

Preferably, the main pixel column and the hidden pixel column according to the present disclosure may be disposed parallel to the diagonal direction of the stretchable display device. Referring to FIG. 6, both the main pixel columns 250a and 250b and the hidden pixel column 260a may be disposed parallel to the diagonal direction of the stretchable display device. In addition, in some embodiments of the present disclosure, the main pixel column and the hidden pixel column may not intersect each other. Preferably, the main pixel column and the hidden pixel column may be disposed alternately and/or parallel on the stretchable display. Referring to FIG. 6 again, after the main pixel column 250a and the hidden pixel column 260a are disposed parallel to each other, the main pixel column 250b may be disposed parallel to the hidden pixel column 260a on the stretchable display device.

The stretchable display device according to some embodiments of the present disclosure may include a data line 230 and a hidden pixel control line 240. In some embodiments, the data line 230 may be a path through which color, brightness, and/or contrast data from a display controller of the stretchable display is transmitted to each pixel. In an embodiment, the data line 230 may be a path for transmitting an RGB color value to the pixel.

In addition, as described above in FIG. 4 and FIG. 5, the hidden pixel control line 240 according to some embodiments of the present disclosure may be a wiring or a path for transmitting a signal related to whether each of the hidden pixels contained in the hidden pixel column 260a disposed on the stretchable display is activated.

Referring to FIG. 6 again, in the stretchable display device according to some embodiments of the present disclosure, the data line 230 and the hidden pixel control line 240 may be arranged alternately and/or parallel on the stretchable display device. Preferably, in the stretchable display, the data line 230 may be connected only to the main pixel columns 250a and 250b, and the hidden pixel control line 240 may be connected only to the hidden pixel column 260a. More preferably, in part or all of a cross-sectional area of the stretchable display device, the data line 230 and the hidden pixel control line 240 may not intersect each other.

In a conventional stretchable display device, when a hidden pixel is used for correcting the image quality while the conventional stretchable display device is stretched, an arrangement in which a single main pixel is surrounded by a plurality of hidden pixels is common. Since this arrangement reduces the number of main pixels existing within the unit area of the stretchable display, there is a problem that the image quality of the stretchable display device is reduced. As described above, in the stretchable display device according to the present disclosure, the number of main pixels per unit area of the stretchable display may be increased by alternately arranging the main pixel column and the hidden pixel column on the stretchable display device. Through this, the problem of the reduction in the image quality of the stretchable display device may be significantly solved. In addition, due to the arrangement of the main pixel column and the hidden pixel column as described above, the number of data lines and the hidden pixel control lines may be significantly reduced. Specifically, according to the arrangement of the main pixel, the hidden pixel, the data line, and the hidden pixel control line of the stretchable display device disclosed in FIG. 3, the number of pixels per inch may be increased by 41% compared to that of the conventional technology, and the number of data channels used to produce the stretchable display device may be reduced by 33% compared to that of the conventional technology. Therefore, in the stretchable display device according to the present disclosure, the production cost may be significantly reduced while the reduction in the image quality according to the stretching is solved.

As described above, the disclosed embodiments of the present disclosure have been described with reference to the accompanying drawings. At least one component may be added or omitted depending on the performance of the components described above. In addition, it will be understood by one skilled in the art that mutual locations of components may be changed depending on the performance or structure of a system.

While the inventive concept has been described with reference to embodiments thereof, it will be apparent to those of ordinary skill in the art that various changes and modifications may be made thereto without departing from the spirit and scope of the inventive concept as set forth in the following claims. The disclosed embodiments are illustrative and should not be construed as limited.

What is claimed is:

1. A stretchable display device provided with a plurality of main pixels and a plurality of hidden pixels, the stretchable display device comprising:
a first main pixel; and
a first hidden pixel corresponding to the first main pixel,
wherein a first hidden pixel value is determined on the basis of a first main pixel value.

2. The stretchable display device of claim 1, wherein the first hidden pixel is positioned adjacent to the first main pixel.

3. The stretchable display device of claim 2, wherein the first hidden pixel value is determined by replicating the first main pixel value.

4. The stretchable display device of claim 3, wherein the replicating of the first main pixel value is performed such that a luminance of the first hidden pixel is equal to a luminance of the first main pixel.

5. The stretchable display device of claim 4, wherein, in the performing that the luminance of the first hidden pixel is equal to the luminance of the first main pixel,
when a control signal for the first hidden pixel is generated, the control signal is applied from an anode of the first main pixel to an anode of the first hidden pixel.

6. The stretchable display device of claim 1, further comprising:
at least one hidden pixel control line; and
at least one data line,
wherein the hidden pixel control line and the data line are alternately disposed.

7. The stretchable display device of claim 6, wherein the hidden pixel control line and the data line are disposed parallel to each other.

8. A stretchable display device provided with a plurality of main pixels and a plurality of hidden pixels, the stretchable display device comprising:
a second hidden pixel; and
a plurality of second main pixels corresponding to the second hidden pixel,
wherein a second hidden pixel value is determined on the basis of a plurality of second main pixel values.

9. The stretchable display device of claim 8, wherein the second hidden pixel is positioned adjacent to the plurality of second main pixels.

10. The stretchable display device of claim 9, wherein the second hidden pixel value is determined by using an average value or a weighted average value of the plurality of second main pixel values.

11. The stretchable display device of claim 10, wherein the determining of the second hidden pixel value by using the average value or the weighted average value of the plurality of second main pixel values is performed such that a luminance of the second hidden pixel is equal to an average value or a weighted average value of a luminance of the plurality of second main pixels.

12. The stretchable display device of claim 11, wherein, in the performing that the luminance of the second hidden pixel is equal to the average value or the weighted average value of the luminance of the plurality of second main pixels, a voltage is distributed by using a capacitor.

13. The stretchable display device of claim 9, further comprising:
at least one hidden pixel control line; and
at least one data line,
wherein the hidden pixel control line and the data line are alternately disposed.

14. The stretchable display device of claim 13, wherein the hidden pixel control line and the data line are disposed parallel to each other.

15. A stretchable display device comprising:
a first main pixel disposed on a main pixel area; and
a first hidden pixel disposed on a hidden pixel area;
wherein the first main pixel comprises a micro LED driving transistor configured to drive a micro LED,
wherein the first hidden pixel is driven according to a hidden pixel control signal, and receives a pixel value through an anode electrically connected to the micro LED driving transistor, and
wherein a luminance of the first hidden pixel is determined by replicating a pixel value of the first main pixel.
